(19) United States
(12) Patent Application Publication
(10) Pub. No.: US 2026/0254197 A1
(43) Pub. Date: Aug. 27, 2026

(54) TUNABLE LASER WITH INTEGRATED CALIBRATION STRUCTURE

(71) Applicants: Tin Komljenovic, Goleta, CA (US); Theodore Joseph Morin, Goleta, CA (US); Igor Kudelin, Santa Barbara, CA (US); Minh Tran, Goleta, CA (US); Boqiang Shen, Goleta, CA (US); Yang Shen, Goleta, CA (US); Bowen Song, Goleta, CA (US); Zeyu Zhang, Goleta, CA (US); Chong Zhang, Santa Barbara, CA (US)

(72) Inventors: Tin Komljenovic, Goleta, CA (US); Theodore Joseph Morin, Goleta, CA (US); Igor Kudelin, Santa Barbara, CA (US); Minh Tran, Goleta, CA (US); Boqiang Shen, Goleta, CA (US); Yang Shen, Goleta, CA (US); Bowen Song, Goleta, CA (US); Zeyu Zhang, Goleta, CA (US); Chong Zhang, Santa Barbara, CA (US)

(21) Appl. No.: 19/064,535

(22) Filed: Feb. 26, 2025

(51) Int. Cl. H01S 5/0683

(52) U.S. Cl. CPC H01S 5/0683

(57) ABSTRACT

An integrated photonic circuit has a semiconductor tunable laser with two tuning elements and an output port providing a first laser output, and a calibration structure The calibration structure has a first reference element having a first reference wavelength response (a primary peak or valley at a first reference wavelength) as the semiconductor tunable laser is tuned by adjusting at least one of the tuning elements. The calibration structure also has a first photodetector. At least part of the laser output from the output port is coupled to the calibration structure. At least part of the first laser output is coupled within the calibration structure to the first reference element; and at least part of the first laser output leaving the first reference element after being coupled thereto is coupled to the first photodetector.

### FIELD OF THE INVENTION

The present invention relates to photonic integrated circuits. More specifically, certain embodiments of the invention relate to semiconductor tunable lasers with improved wavelength control realized as a photonic integrated circuit.

### BACKGROUND OF THE INVENTION

Semiconductor lasers are solid-state lasers based on semiconductor gain media. Most semiconductor lasers are laser diodes, which are pumped with an electrical current in a region where n-doped and p-doped semiconductor materials meet. Common materials for semiconductor lasers (and for other optoelectronic devices) are direct bandgap semiconductors such as GaAs (gallium arsenide), AlGaAs (aluminum gallium arsenide), GaP (gallium phosphide), InGaP (indium gallium phosphide), GaN (gallium nitride), InGaAs (indium gallium arsenide), GaInNAs (indium gallium arsenide nitride), InP (indium phosphide), GaInP (gallium indium phosphide) or others. Indirect bandgap semiconductors such as silicon do not exhibit strong and efficient light emission.

Semiconductor lasers or laser diodes play an important part in our everyday lives by providing cheap and compact lasers used for various applications such as optical communications, sensing, metrology, displays, lighting, material processing and others. Their typical size is in the order of mm, they are made up of complex multi-layer structures requiring nanometer scale accuracy in fabrication and are carefully and elaborately designed for best performance.

A laser is characterized by multiple key parameters such as wavelength of operation, output power, threshold current, wall-plug efficiency, beam quality and others, depending on the application. Of particular interest for many applications are lasers whose wavelength of operation can be altered in a controlled manner; such lasers are commonly called tunable lasers. Tunable lasers are typically single frequency lasers meaning that output power at one frequency is significantly larger than all other peaks in the emission spectrum. The parameter to determine the level of single frequency purity is the side mode suppression ratio (SMSR), defined as the ratio of power in the center peak longitudinal mode to the power in the nearest higher order mode. In some typical cases a threshold of a SMSR >30 dB is considered sufficient to characterize the laser as a single frequency laser. In applications requiring high spectral purity the threshold can be >45 dB or even higher. In yet other applications, where it is hard to provide such high SMSR ratios due to various limitations (e.g. mirror and filter quality), single-frequency lasers can have SMSR of only around 20 dB or lower.

The wavelength of a tunable laser is defined both by the gain medium (defining the spectral range in which lasing is possible) and the cavity comprising the mode-selection filter. There are multiple architectures to provide mode-selection filtering as will be described below, but, in all cases for tunable lasers, one or more controls capable of changing the characteristics of the mode-selection filter are necessary.

Despite the advanced laser designs employed and the high accuracy of semiconductor processing, the output wavelength of a semiconductor laser varies between nominally identically designed devices within a die, between dies across a wafer, and from wafer to wafer, due to differences in layer thicknesses, waveguide widths, sidewall angles, material imperfections and other factors, all of which are present in a practical process. Due to those differences, device calibration is generally necessary.

Calibration is normally performed after fabrication to properly characterize an individual device, and typically utilizes an optical spectrum analyzer or a wavemeter to generate a look-up table (LUT) summarizing the output wavelengths (and, in some cases, other parameters such as e.g. SMSR) as a function of laser control signals (described below). As a laser is operated and ages, this can result in changes in threshold, internal temperatures, defects propagation, physical movements in case of packaged devices (e.g. solder relaxation) limiting the precision of the LUT. This is especially challenging if lasers are to be operated in uncooled environments where ambient temperature can vary over a wide range and provide additional stress to the laser. Due to aging and drift, in some cases the LUT must be regenerated for successful operation of the laser. This increases operational cost, and reduces the useful lifetime of the device as LUT generation has historically required use of external instruments capable of measuring the wavelength or frequency of laser emission.

There is therefore a need for chip-scale tunable semiconductor lasers providing high level of wavelength control and stability that can account for laser aging and changes of external and internal conditions without requiring recalibration. Here we describe such tunable lasers that can regenerate LUT tables without the use of external instruments, to provide stable long-term operation and control, compensating for laser aging and changes in internal and/or external conditions.

### BRIEF DESCRIPTION OF THE DRAWINGS

FIG. 1 (PRIOR ART) illustrates a tunable semiconductor laser device and mechanism to provide wide tuning range.

FIG. 2 shows two embodiments of the present invention shown in top-down view, and illustrative wavelength responses of such embodiments.

FIG. 3 shows an embodiment of the present invention shown in top-down view.

FIG. 4 shows an embodiment of the present invention shown in top-down view and corresponding illustrative diagrams.

FIG. 5 illustrates a device according to one embodiment of the present invention, shown in top-down view.

FIG. 6 illustrates tuning maps of a widely-tunable semiconductor laser according to some embodiments of present invention.

FIG. 7 illustrates a tuning map strategy to provide continuous tuning of a widely-tunable laser according to some embodiments of present invention.

FIG. 8 illustrates a tuning map strategy to detect jumps in wavelengths along the free-spectral ranges of tuning structures according to some embodiments of present invention.

FIG. 9 illustrates a tuning map strategy to change laser wavelength by a predetermined amount according to some embodiments of present invention.

FIG. 10 illustrates advantages of some embodiments of the present invention in relation to tuning maps.

FIG. 11 illustrates flow diagrams for calibration according to some embodiments of present invention that use external components.

FIG. 12 illustrates flow diagrams for calibration according to some embodiments of present invention that use on-chip components.

FIG. 13 illustrates a flow diagram for operation of a widely-tunable semiconductor laser according to some embodiments of present invention.

### DETAILED DESCRIPTION

Described herein include embodiments of semiconductor tunable lasers and related components with improved wavelength control realized as a photonic integrated circuit.

In the following detailed description, reference is made to the accompanying drawings which form a part hereof, wherein like numerals designate like parts throughout, and in which are shown by way of illustration embodiments in which the subject matter of the present disclosure may be practiced. It is to be understood that other embodiments may be utilized, and structural or logical changes may be made without departing from the scope of the present disclosure. Therefore, the following detailed description is not to be taken in a limiting sense, and the scope of embodiments is defined by the appended claims and their equivalents.

The description may use perspective-based descriptions such as top/bottom, in/out, over/under, and the like. Such descriptions are merely used to facilitate the discussion and are not intended to restrict the application of embodiments described herein to any particular orientation. The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The term “coupled with,” along with its derivatives, may be used herein. “Coupled” may mean one or more of the following. “Coupled” may mean that two or more elements are in direct physical, electrical, or optical contact. However, “coupled” may also mean that two or more elements indirectly contact each other, but yet still cooperate or interact with each other, and may mean that one or more other elements are coupled or connected between the elements that are said to be coupled with each other. The term “directly coupled” means that two or more elements are in direct contact in at least part of their surfaces.

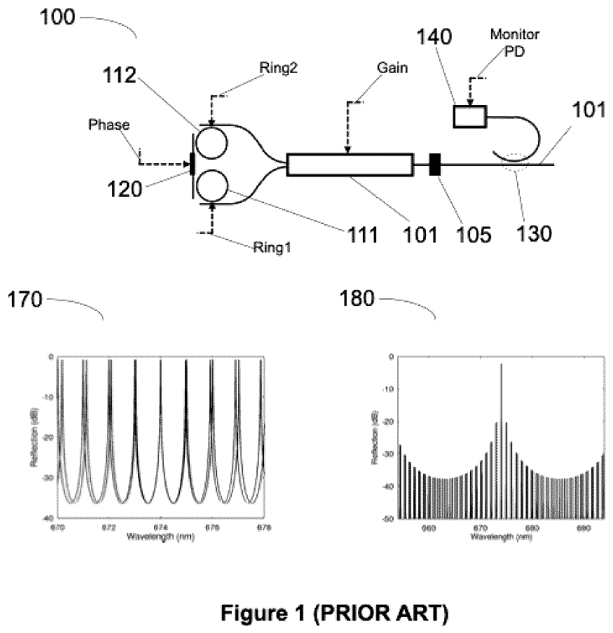

FIG. 1 (prior art) shows a top-down view of a tunable laser device (100) utilizing ring-resonator-based frequency selective filters, capable of providing wide tuning ranges. Such lasers are sometimes called ring-resonator-based (RRB) tunable lasers. In the embodiment shown, two ring resonators (111) and (112) in add-drop configuration are used to provide frequency-selective feedback, but various other arrangements are possible. Add-drop couplers (coupling in and out of the ring resonators) are, in some embodiments, directional or pulley couplers in which coupling strength can be well controlled and coupler losses optimized. Each ring has multiple resonances in the frequency/wavelength domain, as shown in view (170) where wavelength responses of two rings are shown, with their spacing determined by the free-spectral ranges corresponding to the inverse of the round-trip times taken to travel though each resonator. Each resonator (111) and (112) has a tuning element with a corresponding control signal (Ring1 and Ring2). In most cases the tuning element is a heater that can change the resonant condition/wavelength of the resonator by changing the effective index of the resonator waveguide via the thermo-optic coefficients of the materials forming resonator. In some embodiments, non-thermal tuning mechanisms are utilized—e.g. electro-optic tuning, stress induced tuning, carrier induced tuning or others. By designing two (or more) ring resonators to have slightly different round-trip times, wide tuning can be realized in their combined output utilizing the Vernier effect as shown in view (180) where combined wavelength response of the two rings from view (170) is shown. As the responses of the two rings are slightly different-by having the free-spectral ranges offset by a small amount-their responses only align well at one single frequency in a broadband wavelength range, allowing that corresponding single longitudinal mode to be selected to provide single-frequency lasing. Furthermore, this allows tuning over much broader tuning range with relatively low drive power, as each ring only has to be tuned by one free-spectral range to cover a much broader output wavelength range supported by the laser gain material using the Vernier effect. At the same time, however, this results in challenges related to the quality of LUTs, as changes of external conditions or laser aging can cause the laser to jump to a “wrong” wavelength.

In the embodiment shown in view (100) the light from gain region (101) is reflected back and forth between the ring resonator region that acts as a back-side, frequency selective mirror and element (105) which acts as a simple front mirror. In some embodiments, RRB tunable lasers also comprise a phase section/tuner (120) that enables tuning of the longitudinal modes utilizing a Phase section control signal to allow alignment of the longitudinal mode locations to the frequency response of the resonators. The phase tuner, in most cases, is also a heater that changes the effective index of the waveguide via its own thermo-optic coefficient, but it may also utilize other tuning mechanisms as described above in relation to tuning of the resonators.

In this exemplary prior art laser, a photodetector 140 is present.

Narrow-band tuning, performed by careful control of all tuning signals, allows continuous tuning over a limited range (10 s of GHz range nominally). Wide-band tuning (THz+range) is realized utilizing the Vernier effect of a combination of resonators. When providing wide-band tuning, the laser can mode-hop producing both phase and frequency discontinuities. RRB tunable lasers can typically provide more than several THz of tuning range (with the above-mentioned mode-hops), but due to fabrication imperfections, packaging and other effects discussed above, the output wavelength varies between nominally identical devices driven by identical control signals. A look-up table (LUT) can be generated corresponding to the driving conditions (e.g. current supplied to each resonator) needed for the laser to operate at each particular wavelength. Additionally, the phase section can be tuned to align the longitudinal modes to the peak of mirror reflectivity and improve laser performance. The LUT is commonly generated by sweeping the control signals applied to the mirrors (and the phase section) and recording the output wavelength, and other relevant parameters (e.g. SMSR, output power). Determination of wavelength and SMSR typically requires external instruments, such as wavemeters or optical spectrum analyzers, capable of providing such measurements. If the relevant parameters are considered acceptable, the settings (tuner control signals) and corresponding wavelengths) can be stored as an LUT in a memory and the laser can be controllably tuned to the desired wavelength condition using the stored settings. An even more elaborate LUT can add additional control parameters to account for different laser operating temperatures and gain currents-although this can significantly increase the time needed to generate the LUT, as the number of control parameters increases from two (corresponding to the basic case of just tuning the two rings via Ring1 and Ring2) to five (two rings, phase, laser gain, laser temperature) or even more in the case of additional controls (e.g. third ring, etc.). The problem with relying on LUTs generated after the lasers are fabricated but prior to routine operation is that lasers typically age over time and use, resulting in changes in their parameters including threshold, output power, differential efficiency, etc., in turn resulting in reducing the precision of the pre-calibrated LUT. This may cause the lasing mode to jump to a wrong (unintended) Vernier-determined peak, resulting in a significant wavelength difference between the desired wavelength, which the control signals are intended to set, and the actual laser output. Correcting for this issue, prior to the present invention, requires utilizing external instruments to re-generate the LUT, updating its contents to the extent necessary.

Like RRB lasers, sampled-grating distributed Bragg reflector (SGDBR) lasers (not shown) are also capable of providing wide tuning ranges. In this type of laser, the SGDBR laser mirrors are realized as a sampled periodic structure (grating), resulting in multiple reflectivity peaks in the spectral domain. These peaks are spaced apart in the spectral domain at a period inversely proportional to the period of the sampling of the grating in the physical space. The two mirrors of the laser are sampled at different periods such that substantially only one of the multiple reflection peaks of one mirror coincides with a peak from the other mirror in the optical bandwidth range defined by the gain medium, as may be understood in terms of the Vernier effect, similarly to the case of RRB lasers. In some embodiments, the SGDBR mirrors have different reflectivities, with one mirror (the front or output mirror) having lower reflectivity and consequently the laser outputs more power in this direction. The tuning of SGDBR lasers is similar to that of ring-resonator based tunable lasers and can provide narrow-band tuning (with careful control of all tuning signals), and wide-band tuning utilizing the Vernier effect (at the cost of having mode-hops).

Two common types of tunable semiconductor laser are described above, but various other arrangements of resonators and/or sampled gratings to realize lasers are possible, including changing their positions, coupling locations, and/or number as is known in the art of widely-tunable semiconductor lasers. Other types of tunable lasers (such as coupled cavity lasers) are also possible.

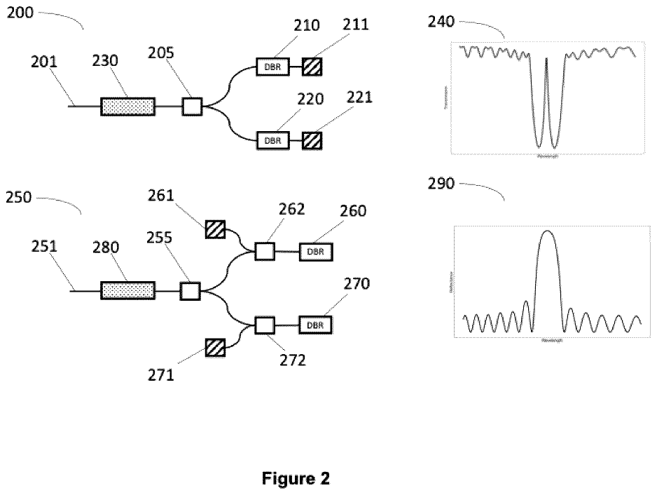

FIG. 2 shows a top-down view of two versions (200) and (250) of a calibration structure that may be used in some embodiments of the present invention, and two illustrations (240) and (290) of the wavelength responses of some illustrative reference elements, such as (210) or (220), and (260) or (270) respectively that can be a part of the calibration structure.

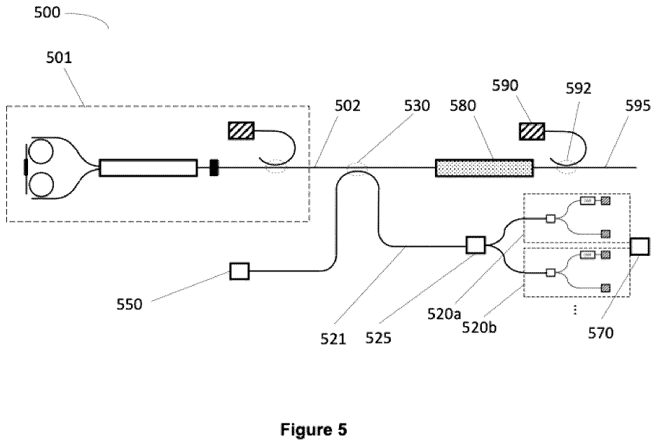

Calibration structure (200) comprises an input port (201) that is coupled to the output of the laser (not shown) as will be described in more detail below in relation to FIG. 5. In some embodiments, the laser output passes from input port 201 through semiconductor optical amplifier (SOA) (230) that can provide signal amplification when operated in forward bias but can also provide a high-level of isolation when reverse biased. The latter can be helpful in preventing any feedback from the calibration structure from impacting the laser during operation, when the calibration structure is not being utilized. In other embodiments, not shown, there is no SOA (230) present.

In the embodiment shown in view (200), the laser output is split after passage through SOA (230) into two parts in the splitting element (205). This splitting element can be a directional coupler, multi-mode interference coupler, adiabatic coupler, inverse-design coupler or any other structure that can split the input signal into two or more outputs. Each of the outputs from splitting element (205) is then routed to a corresponding reference element, (210) and (220) respectively, passing through it before arriving at a corresponding photodetector element (211) and (221). The reference elements, in some embodiments, are Bragg gratings. A Bragg grating is a waveguide with a periodic variation of refractive index, so that a large reflectance (corresponding to a small transmission) occurs over a limited wavelength range (bandwidth) around a certain wavelength which fulfills the Bragg condition. Various designs of Bragg gratings can be implemented, including gratings using corrugations on the waveguides, posts at the sides of the waveguide, multilayered structures to provide periodic feedback, etc. In yet other embodiments, a Bragg grating can have defects that provide sharper features as will be explained with the help of view (240); alternatively, it may comprise a sampled grating to provide a periodic response as described above in relation to the SGDBR laser of FIG. 1. In yet other embodiments, the reference element can be any element with a distinct wavelength/frequency transmission response that can be utilized to determine the wavelength of the incident laser signal. In the shown embodiment, the power incident on the photodetector (211) depends on the transmissivity of reference element (210), while the power incident on the photodetector (221) depends on the transmissivity of reference element (220). Both transmissivities are a function of wavelength, so the response from the photodetector can be utilized to detect the incident wavelength.

In general, reference elements used in embodiments of the present invention are characterized by wavelength responses that comprise sharp features that are easily seen against a background of features of much lower (or higher) magnitudes. These sharp features occur at wavelengths specific to the reference elements, and are defined in this disclosure as “primary” peaks or valleys respectively.

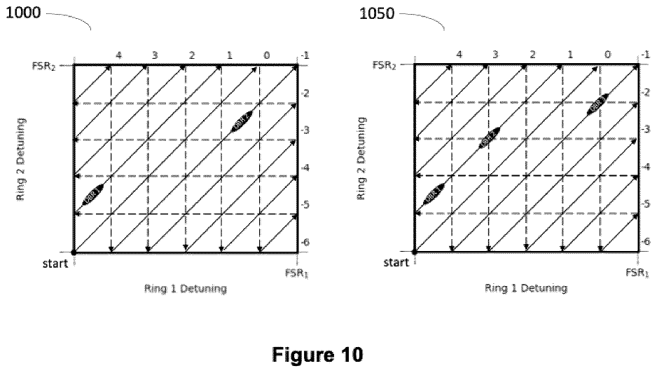

More specifically, in some embodiments the reference element is a Bragg grating with a defect (phase shift), causing the transmissivity to follow a desired curve such as that shown in view (240), where there is a reduction in transmission over most of a range of wavelengths around the Bragg condition match, but, due to the defect, there is a sharp increase in transmission in a relatively narrow range at the center of that Bragg condition match wavelength. This sharp peak can be easily detected by the photodetector to precisely determine when the laser output wavelength matches the Bragg grating wavelength. In the embodiment shown in view (200) there are two reference elements, but in general sense at one extreme there can be as little as a single reference element (and in such case splitting element (205) might not be present), and in the other extreme there may be many more than two reference elements (10 s or more) using suitable splitting elements and/or cascades of splitting elements (not shown). The advantages of using more than one reference element will be explained below, in the discussion of FIG. 10.

Calibration structure (250) is a similar structure to calibration structure (200), and functional elements (251) to (280), unless explicitly defined differently, correspond to functional layers (201) to (230) as described in relation to calibration structure (200). A difference between structures (250) and (200) is in the introduction of elements (262) and (272) that serve as additional splitters to enable the use of reference elements (260) and (270) in a reflection configuration. The laser output, after being amplified in SOA (280) if the SOA is present, is split in element (255) and then each portion is incident on one of elements (262) and (272) that serve as splitters for any signal that is reflected back from elements (260) and (270), such that a part of each reflected signal is incident on a corresponding photodetector (261) or (271). In some embodiments, the reflection spectrum of each reference element realized as a Bragg grating with a response following a desired curve such as that shown in view (290) where the actual shape is a function of grating strength and length (number of periods). In yet other embodiments, the reference elements can be any elements with distinct wavelength/frequency reflection responses that can be utilized to determine the wavelength of the incident laser signal. In the embodiment shown in view (250) there are two reference elements, but there may be as few as one single reference element, or many more reference elements (10 s or more) using suitable splitting elements and/or cascades of splitting elements (not shown).

In other embodiments, not shown, a calibration structure can comprise two photodetectors per reference element (one each after (260) and (270) for example) to monitor both transmission and reflection.

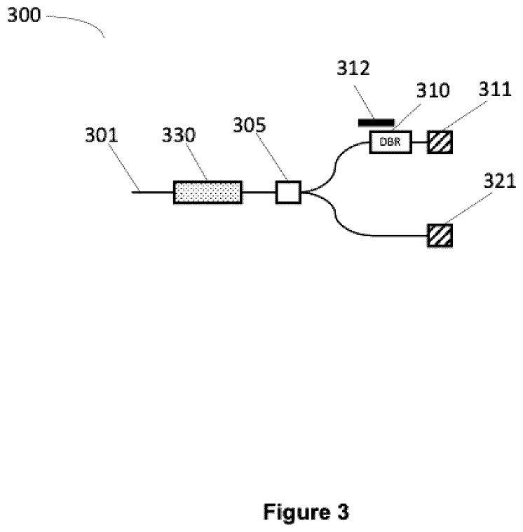

FIG. 3 shows a top-down view (300) of a calibration structure that may be used in some embodiments of the present invention, that utilizes an additional reference photodetector (321) in an arm without a reference element to provide improved performance and robustness of the calibration structure.

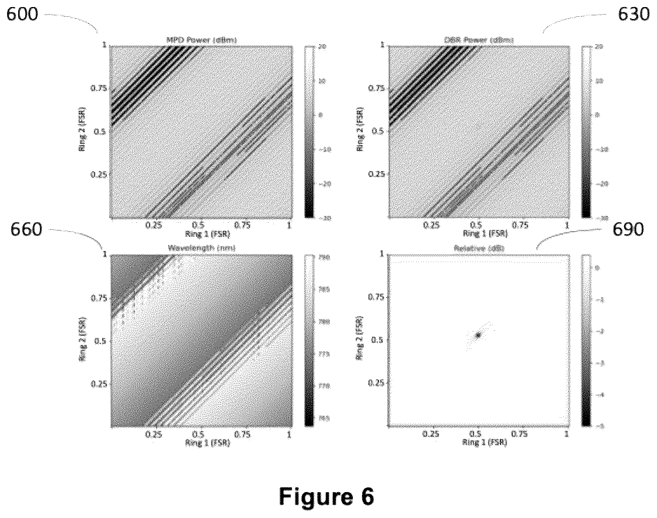

Functional elements (301) to (330), unless explicitly defined differently, correspond to functional layers (201) to (230) as described in relation to calibration structure (200) in FIG. 2. As the determination of the wavelength using a reference element (310) is based on measuring the optical power incident on a photodetector (311), potential variations in laser output power and/or wavelength sensitivity of the components used to couple the laser to the reference element (as will be described in more detail with the help of FIG. 5) can impact the performance of the calibration structure. To improve performance, in some embodiments, the calibration structure may, like the one shown in FIG. 3, include a monitor arm with no reference element. Before being incident to the reference element, the input light is split into two or more arms, such that part of the light enters the monitor arm and is coupled to a corresponding photodetector (321), allowing power variations that are not a result of the reference element (310) to be monitored. The two responses of the photodetectors (311) and (321) can be compared and/or subtracted either directly or using processing in electronic control circuitry. This approach can greatly improve the sensitivity of the calibration structure as will be described in more detail with the help of FIG. 6. It is obvious that various arrangements providing similar functionality (minimizing the influence of any power variation that is not a result of the reference element) can be envisioned for various calibration structure architectures.

In some embodiments, the calibration structure can also comprise a tuner (312). Tuner (312) can be a heater that can change the resonant condition/wavelength of the reference element (310) by changing the effective index via the thermo-optic coefficients of the materials. In other embodiments, tuning mechanisms based on electro-optic tuning, stress induced tuning, carrier-induced tuning or other effects can be used. Tuning can allow an additional degree of control of the reference element, and can also be paired with temperature monitoring using a thermistor element as will be described below in relation to FIG. 5.

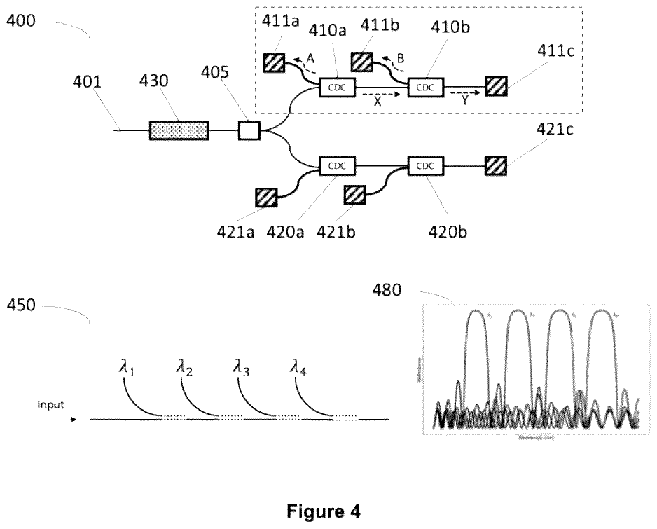

FIG. 4 shows a top-down view (400) of a calibration structure that may be used in some embodiments of the present invention, and two illustrations (450) and (480) showing how this structure can provide frequency/wavelength selective responses suitable for providing calibration structure functionality.

Calibration structure (400) is a similar structure to calibration structure (200), and functional elements (401) to (430), unless explicitly defined differently, correspond to functional layers (201) to (230) as described in relation to calibration structure (200). A difference between structures (400) and (200) is in the use of a contra-directional coupler (CDC) as a reference element. A CDC is a directional coupler with a grating that reflects signals of a particular wavelength, or in a particular wavelength range, entering the coupler from an arm on one side of the coupler back into another arm on that same side of the coupler. In the embodiment shown in view (400) the calibration structure comprises one splitting element (405) that then feeds into two arms, each comprising two CDCs, and three photodetectors. The upper arm, roughly indicated by the dashed rectangular box, comprises a first CDC (410a) whose reflected signal (see dashed arrow A) is coupled to photodetector (411a) while its transmitted signal (see dashed arrow X) is coupled to a second CDC (410b). The signal reflected by CDC 410b is coupled (see dashed arrow B) to photodetector (411b) while its transmitted signal is coupled (see dashed arrow Y to photodetector (411c). This enables the measurement of the two “reflected-coupled” signals, detected by 411a and 411b respectively, as well as the signal transmitted through both CDCs, detected by 411c. The lower arm, in this shown embodiment, functions in the same way using CDCs (420a) and (420b), and photodetectors (421a), (421b) and (421c). Various other arrangements, using different numbers of CDCs and photodetectors, as well as different arrangements can be used to effectively provide similar functionality—wavelength sensitive responses that can be used to calibrate and control the laser as will be described in the remainder of the specification.

View (450) shows an illustration of an input waveguide coupled to four CDC structures each reflecting a different wavelength range (λ₁, λ₂, λ₃ and λ₄) back into the “reflected-coupled” arm output. View (480) shows corresponding illustrative reflected spectra for four such CDCs showing that they can be utilized to determine the incident wavelength by measuring the responsivities of the photodetectors coupled to the “reflected-coupled” arms of the CDCs. Various other arrangements of CDCs and photodetectors, including different splitting element configurations can be envisioned to provide similar functionality.

FIG. 5 shows a top-down view of an embodiment (500) of a photonic integrated circuit that is representative of a category of embodiments that include a tunable laser together with one or more calibration structures to provide improved wavelength control of the laser. In the particular example illustrated, tunable laser (501) is a RRB laser as described above in relation to FIG. 1, and two such structures, (520a) and (520b) are present. In other embodiments, the laser may be a SGDBR laser or any other widely-tunable laser. Coupler (530) taps the laser's output (502). Coupler (530) can be a directional coupler, multi-mode interference coupler, adiabatic coupler, inverse-design coupler and any other structure that can split the input signal into two or more outputs. In some embodiments, between 0.1% and 5%, of the laser's output (502) is tapped by coupler (530) and routed through waveguide (521) to the calibration structures. In other embodiments, the tapping can be smaller or larger, depending on specific factors like the laser output power and sensitivity of the calibration structures. Each of the two calibration structures shown corresponds to calibration structure (300) as described above in relation to FIG. 3, but any other calibration structures that provide distinct wavelength selective responses, preferably with sharp features that are easy to distinguish, can be used, and their number can vary between one and three or even more, as will be described below. A splitting element (525) is used to provide laser input power to both calibration structures, as described above for splitting element (205) or (255) in FIG. 2. In cases where only one calibration structure is present, there is no need for splitting element (525). In cases where there are more than two calibration structures, either a different splitting element with a correspondingly larger number of outputs, or a cascade of splitting elements, or both can be used. In some embodiments, the part of the laser output that passes through coupler (530) without being tapped into waveguide 521 enters a semiconductor optical amplifier (580) before reaching output (595). The output from semiconductor optical amplifier (580) can also be tapped via coupler (592) to reach photodetector (590). Photodetector (590) can enable precise output power monitoring, and also allow intensity noise to be reduced using a feedback loop (not shown) to semiconductor optical amplifier (580). Various arrangements of the laser, amplifiers and photodetectors can be envisioned before the final output (595) of the device. In some of these embodiments, there is no SOA present.

In some embodiments, an input (550) can be used to introduce a signal from another laser to the calibration structures. In some embodiments, input (550) can be a grating coupler or similar structure that is suitable for coupling optical signals on a wafer scale, while in other embodiments, it can be an edge coupler. The purpose of input (550) is to allow the output of an external laser to be injected into calibration structures (520a) and (520b), which can enable their own wavelength responses to be calibrated, as will be described below. This additional calibration may be needed because of the semiconductor process variation already discussed, that can result in slight differences in wavelength responses between nominally identical structures. Process variations such as thickness variation, material refractive index variation, and sidewall angle variation, for example, can impact the wavelength response of the calibration structures themselves. Regardless of these variations, by injecting the output of an external laser with controllable and known wavelength into input port (550) we can measure and record the wavelength responses of the calibration units (and their reference elements). These responses can be suitably recorded and saved in memory for future use as will be described below. In some embodiments, there is also at least one thermistor element (570) positioned suitably close to the calibration structures to enable calibration at various temperatures (using heaters integrated into the calibration structures, or external heaters to control wafer/chip substrate temperature) and also to measure the temperature of the calibration structures during device use.

In other embodiments, input port (550) is not present, and calibration can utilize laser output (595) and an external instrument (wavemeter or optical spectrum analyzer). In this case, laser (501) is suitably tuned and the responses of the calibration structures are recorded while precise wavelength is determined via the external instrument.

Various other combinations of elements, such as multiple lasers, different coupling schemes to the calibration structure, different arrangements of the lasers, can be utilized, but in all embodiments a small part (<50%) of the laser output(s) is coupled to at least one calibration structure. Some algorithms to control the laser using calibration structures are described below.

The use of a reference-free monitor arm with an additional monitoring photodetector (not shown), like photodetector (321) as described above in relation to FIG. 3, can help to correct for the wavelength dependence of laser output power, as well as for the effect on transmitted power of the wavelength dependence of various coupling structures such as e.g. (530), (525), input port (550) and/or other structures that exhibit wavelength dependent characteristics to provide improved performance and robustness of the calibration structure.

FIG. 6 shows four plots characterizing aspects of the tuning of a widely-tunable laser as used in some embodiments of the present invention. In the particular case illustrated, the laser is assumed to have two ring resonator tuning elements, as in the prior art case illustrated in FIG. 1, but they could be sampled gratings or other types of tuning elements, and in other embodiments there could be more than two. The laser, whose power is monitored during the tuning, also has a phase tuner (whose control signals are assumed but not shown in FIG. 1) that is assumed to be tuned such that the longitudinal lasing mode is perfectly aligned at each ring resonator configuration.

The plot in view (600) shows the power reading from a monitor photodetector (MPD) as the RRB laser is tuned across the full tuning range achievable; this is done by tuning each ring resonator through its own full free spectral range (FSR). The MPD reading can be the reading of a photodetector that is a part of the laser, e.g. detector (140) as described in relation to FIG. 1, but it is preferably the reading of a monitor photodetector in the calibration structure, such as photodetector (321) as described in relation to FIG. 3. Notice that in either case, the MPD reading is not affected by any reference element (such as 310). The benefit of using a monitor photodetector like photodetector (321) in an external (to the laser) calibration structure is that it accounts for the imperfections of not just the laser and ring resonators but other components as well, such as couplers that could cause additional power variations. Tuning is done by adjusting each tuning element (ring resonator) to cover its full spectral range (before responses repeat). As the phase is optimized (meaning the longitudinal mode is aligned to that required for minimum cavity loss), the output power in this plot is pretty uniform, but there are power variations at the edges of the gain peak (edge of tuning range). The plot shown in view (660) shows the corresponding wavelength of the laser as the laser is tuned across the full tuning range.

The plot shown in view (630) shows the reading of a monitor photodetector (MPD) in the calibration structure, such as photodetector (311) in FIG. 3, that measures optical power as a response of the reference element (such as (310) in the example of FIG. 3). This plot shows power variation as the laser is tuned across the resonance of a distributed Bragg reflector (DBR) grating in this example, but the effect of the DBR is hard to see, simply looking at this plot, due to the relatively large power variations of the laser at the edges of the tuning range.

The plot shown in view (690), however, shows the difference between views (600) and (630) by directly subtracting the powers at corresponding FSR-normalized tuning values. This shows there is significant variation in the output powers recorded by the two photodetectors in the region where the laser is tuned through the characteristic feature of the DBR grating. The comparison between view (630) and (690), where the effect of the grating element is much more visible in view (690), shows the advantage of using a two-arm structure such as that described in relation to FIG. 3 where there is one monitor photodetector in an arm with the DBR grating and a second monitor photodetector in a monitor arm without the DBR grating. This approach also allows for the removal of wavelength dependent characteristics of other elements.

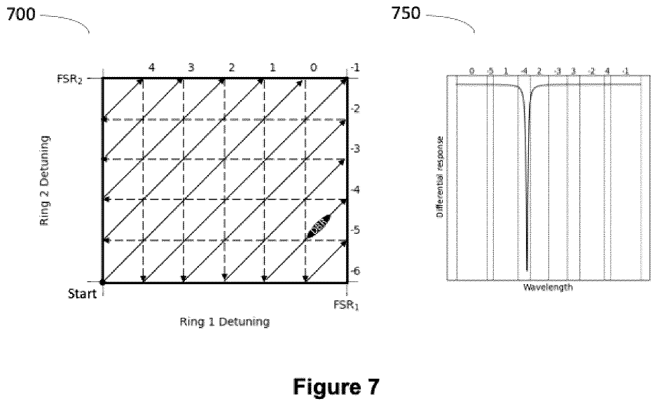

FIG. 7 shows a tuning strategy that allows the laser to cover the full tuning range in quasi-continuous (typically with mode hops) mode using just one free-spectral range (FSR) of each ring resonator, feeding the laser output into a calibration structure like that shown in FIG. 3 (or FIG. 5), where one detector (like detector (311)) is in an arm including a single DBR reference element (like (310)) and another detector (like detector (321)) is in an arm without a reference element. View (700) shows the movement on a tuning map similar to one shown in view (660), while view (750) shows the differential signal obtained by subtracting the responses of the two monitor photodetectors, (such as (321) and (311) in FIG. 3) as the laser is being tuned across the full tuning range, that includes the matched wavelength of the DBR reference element.

In view (700), the tuning begins at the point marked “Start” corresponding to zero de-tuning of the tuning elements, or rings in this case where an RRB laser is assumed. In the case of an SGDBR laser, it would be the zero-detuning of the gratings, and similarly for other types of lasers. Zero de-tuning means that no control signal is applied to the tuners. The tuning, in some embodiments, starts moving diagonally along the first arrow that ends up at the point marked “0” by applying the appropriate control signals to the two tuning elements. To tune diagonally in this way, typically the two tuning elements are operated such that their resonances align and move together, while a phase tuner (such as element (120) in FIG. 1) can be operated for the longitudinal mode to track the resonances. If the phase tuner has sufficient range, this tuning along the diagonal line ending up at point “0”, referred to for convenience as the 0 line. Could be mode-hop free, while in cases where the phase tuner cannot provide sufficient tuning range, the laser might mode-hop while transversing the diagonal. As one of the rings reaches its FSR limit, we can reset that tuner (change the tuner to zero de-tuning, causing a mode hop) following a dashed arrow that goes vertically down from 0, after which we can start tuning to follow the −5 diagonal line (the line ending at point “−5”). In general, it is expected that one ring will hit its FSR limit at a different time than the other ring, as they must have slightly different FSRs to achieve the Vernier effect. Now, when the other ring reaches its own FSR limit, it is reset, moving left along a horizontal line before it is tuned to start following the 1 diagonal line. This process can then continue until the full tuning map is covered, following the arrows in the diagram. When the laser reaches the −4 diagonal, it scans across the match conditions for the illustrative DBR, resulting in a drop in power on the detector in the reference arm of the calibration structure, measuring the wavelength response of the reference element. This complete path along all the diagonal curves can be “un-wrapped” as shown in view (750) where the laser wavelength is tuned along the whole sequence of diagonals 0, −5, 1, −4, 2, −3, 3, −2, 4 and −1 in this illustrative case, including the portion where it scans though the match wavelength of the reference element, while going through diagonal −4. Although view (750) shows a continuous wavelength sweep from the lowest to the highest wavelength, this is only true if the zero-detuning or start point corresponds to the shortest wavelength at which the laser can operate (which it does in this case, as indicated in view 700).

In cases where the start point is not at the shortest wavelength at which the laser can operate, then the laser would start at some other wavelength inside the tuning range, move in one direction towards the end of the tuning range and then reset before arriving back to the starting wavelength. In yet other embodiments, a laser might have a dead-zone where lasing is either not possible or it is not single-frequency—this depends on the gain bandwidth and the designs of the rings. Either of these cases can be monitored with on-chip photodetectors as there will typically be large drops in power detected. In some cases, scanning can also tune rings (or gratings) by more than one FSR as their response is generally periodic, but this can require more tuning power, that could negatively impact laser performance (e.g. increase temperature due to additional heat dissipated on resistors used to thermally tune the rings/gratings). It is generally beneficial to limit tuning in practical operation to as close as possible to one FSR, but allowing for e.g. 110% or more of the tuning range can simplify operation and also allow continuous tuning around a larger set of frequencies (before reaching the “reset” point that causes a mode-hop).

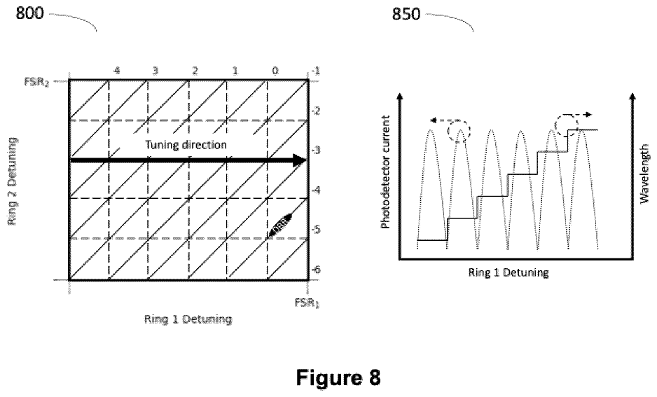

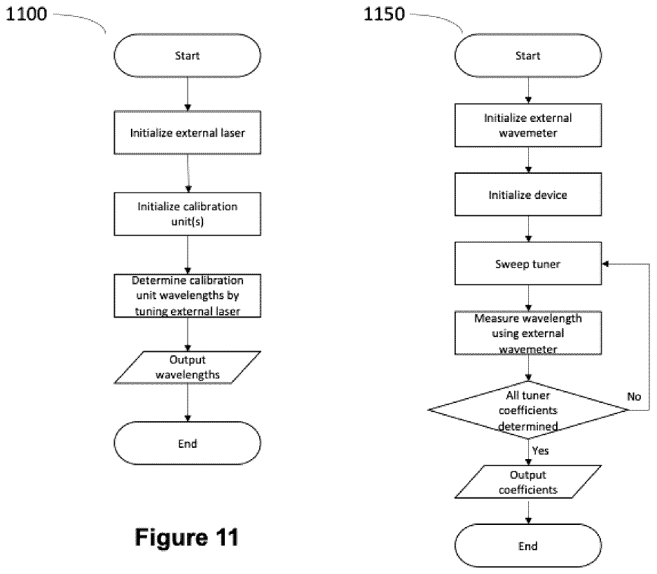

FIG. 8 shows a tuning strategy that allows us to calculate, or “calibrate” the powers needed to cause the laser mode to jump from one Vernier match to the next, using either of the two tuning elements in this two-tuning-element case. The same idea can be generalized and applied to lasers with a larger number of tuning elements. View (800) shows what occurs when Ring 1 is tuned while the control signals for Ring 2, the phase heater or any other tuning element are kept constant. As Ring 1 is tuned (as indicated by the horizontal arrow), the laser will jump between the FSRs of Ring 1, and in each jump the wavelength will change by that corresponding FSR, which can be detected by fluctuations of the power incident on a suitable photodetector, as shown in view (850). The size (height) of the steps (in wavelength or frequency) can be measured/calibrated either on a wafer scale, as will be described in more detail with the help of FIG. 11 or on a (singulated) device level. The size of the steps is very stable in time as it is primarily defined by material properties (defining the mode effective index) and the geometry (length of the resonators) of the device, with temperature and other variables having only minor impacts. Furthermore, the impact of temperature can be easily calibrated out if temperature is controlled or measured. If measured, the change of refractive index with temperature is straightforward to characterize, and if it is not, it may be estimated by data in the literature. This response periodicity, as shown by the varying photodetector current, can be obtained for any tuner element, and allows the laser calibration to be checked and the number of FSR jumps to be tracked. Tuning a phase tuner will similarly result in jumps in photodetector current allowing the calibration to be checked and the number of jumps to be tracked, including determining the power needed to tune the phase by 2π (which corresponds to one full FSR for the tuning element). Jumps are typically similar between nominally identical devices, but their start wavelengths (where there is no signal applied to tuners) typically varies due to fabrication imperfections, as the starting wavelength is dependent on precise phase relationships inside the cavity and tuner elements.

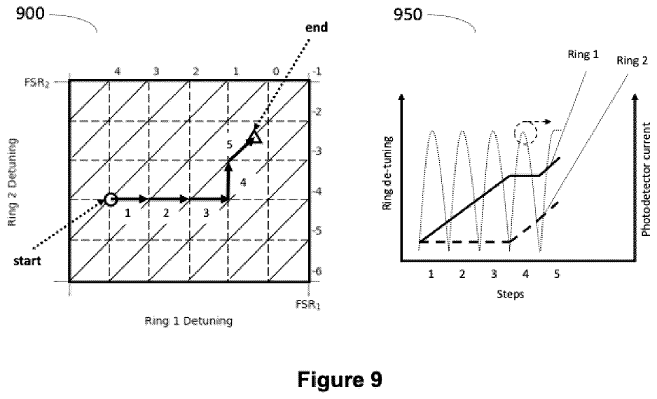

FIG. 9 shows a tuning strategy that allows the laser to move from one wavelength (marked with a circle) to another (marked with a triangle). By knowing the FSRs of both rings, and being able to monitor the jumps as described above in relation to FIG. 8, we can monitor the number of jumps required for each ring's tuning to achieve the desired final wavelength. In the example shown, after three jumps for Ring 1 and one jump for Ring 2, the final wavelength is reached. Other paths to move between the two wavelengths are possible, involving joint tuning of the two rings (using the MPD readings to make appropriate phase adjustments to keep all the tuning elements aligned).

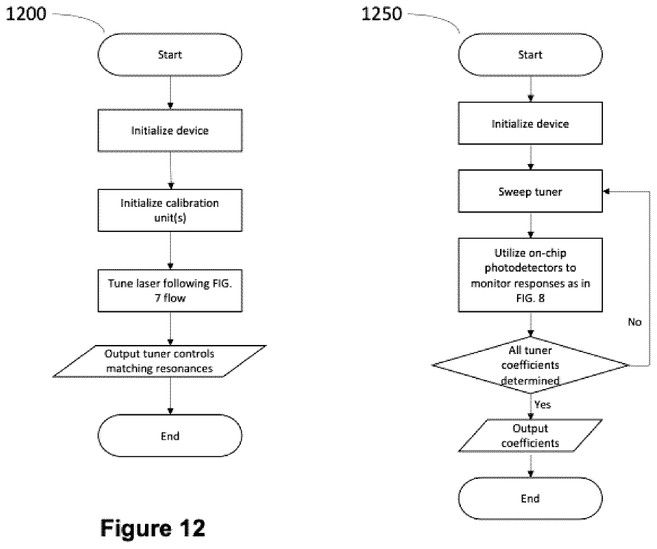

This step-wise tuning can be helpful during calibration, diagnosis or similar operations, but in cases where we need the tuning to happen as quickly as possible we can simply calculate the necessary tuning signals from a laser LUT (that can be pre-calibrated as will be explained below with relation to FIGS. 11 and 12) and apply them to jump directly from one wavelength to another. During this time, the output wavelength can be undetermined for a brief time, and if this is a problem for the specific application, the output SOA (if present) can be used to effectively gate the laser off with reverse bias.

A laser look-up table (LUT) can be generated in multiple ways, as will be described below in more detail, including the use of external components. As the laser ages, or external conditions change (such as temperature, stress, etc)—the tuning map might change, primarily due to small phase differences inside the tuning elements resulting in wavelength jumps. The FSRs of the tuning elements, as described earlier, are typically very robust, but the actual resonant wavelengths of the tuning elements are more sensitive, as they are defined by phase relationships. We generally use this higher sensitivity to enable tuning with lower powers, but this also causes challenges in LUT stability.

With only one reference element (with a known reference wavelength) present, as in the cases corresponding to FIG. 7, we can always check if the LUT has drifted by applying the drive conditions corresponding to that wavelength. If the laser tunes correctly, we can assume the LUT is correct, and if we do not hit the reference wavelength, we can assume that LUT is not valid anymore. We can then initiate linear tuning until the element's characteristic reference wavelength is matched, after which, assuming that the tuning efficiencies of the tuner elements have not changed, we can reconstruct the tuning map using the power values needed to tune the rings by a whole FSR and the power value(s) needed to tune the phase. To further improve on this, we can also check the FSR tuning using the tuning procedures as explained above in relation to FIG. 8. This can help to recover the tuning map in some cases where the drift has not been too great, but in other cases the drift may have been so great that we may not be able to determine when the laser jumps over the full Vernier range, e.g. from minimum to maximum wavelength.

Views (1000) and (1050) in FIG. 10 illustrate cases where more than one reference element is present in the calibration structure. Having two reference elements with different characteristic wavelengths can help us determine the Vernier FSR, by noting the points at which the wavelength jumps from its maximum value to its minimum value, or vice versa.

We can also introduce a third reference element as shown in view (1050). With proper placement, this allows us to measure the rings' FSR jumps, the Vernier FSR jump (between the extremes of the laser minimum and maximum wavelength) and the diagonal laser tuning ratio (ratio of control signals delivered to individual tuners needed to keep tuners aligned for continuous/diagonal tuning). In some embodiments we can have two reference elements that are spaced pretty far apart in the tuning map—this allows for recalibration of FSR jumps as well as the Vernier FSR jump, while a third reference element can be close to either of the other two elements to allow us to check and calibrate diagonal tuning utilizing all tuner elements at the same time. Finally, adding additional elements (beyond three) can further increase the precision, as might be needed in some particular applications. In yet other embodiments, we can introduce a reference element whose reference wavelength closely matches the intended lasing wavelength, e.g. systems using Rb-atoms and their transition around 780 nm might comprise a laser structure with at least one reference element placed around 780 nm which allows us to pre-tune the laser before e.g. locking to the Rb-atom, etc. This can simplify the operation of the laser, and also provide improved robustness of the systems.

FIG. 11 shows two flow diagrams illustrating some algorithms that can provide calibration of some of the components in embodiments of the present invention, in cases where external elements are used.

View (1100) shows an illustrative flow of steps for calibrating the calibration unit(s) using an external laser and input port, as discussed above in relation to FIG. 5. In this illustrative embodiment, the calibration starts by initializing the external laser before initializing the calibration unit(s). Initialization can include operations such as turning on, thermalizing and providing other operations needed for devices to reach an optimal operating state. Once the external laser and calibration unit(s) are properly initialized, we can tune the external laser and determine precise wavelength responses of the calibration unit(s). The reason for calibration is the semiconductor process variation that can result in slight differences in wavelength responses between nominally identical structures. Process variation such as thickness variation, material refractive index variation, sidewall angle variation and similar can impact the wavelength response. Regardless of these variations, by using an external laser with a controllable and known wavelength that is injected via an input port (such as port (550) in FIG. 5) we can measure and record the wavelength responses of the calibration unit(s)and save them in memory for future use as will be described below. Calibration can be performed at several temperatures to further extend the precision of measurements. This calibration can be performed per design (ignoring fabrication variations), per wafer (to account for per wafer variations), per die (to account for large scale intra-wafer variations) and per device (to fully account for all variations on individual device level), with per device calibration being preferred for best performance, but of course this also needs the largest number of measurements, as each device has to be calibrated.

View (1150) shows an illustrative flow of steps for calibrating tuning elements using an external wavemeter, optical spectrum analyzer or other measurement device providing similar capabilities. To simplify, for the remainder of this disclosure, we will use the term wavemeter to mean any device(s) that can detect the wavelength of an optical source. In this illustrative embodiment, the calibration method starts by initializing the external wavemeter before initializing the device being tuned (i.e. the tunable laser). Initialization can include operations such as turning on, thermalizing and providing other operations needed for devices to reach an optimal operating state. Once the wavemeter and tunable device are properly initialized, we can tune each of the tuning elements while measuring the wavelength using the wavemeter, and determine the FSRs of each of the tuning elements including their tuning coefficients (e.g. wavelength change as a function of applied control signal to the tuner). Once these parameters/coefficients are determined they can be suitably recorded and saved in memory for future use as will be described below. Calibration can be performed at several temperatures to further extend the precision of measurements.

This calibration can be performed per design (ignoring fabrication variations), per wafer (to account for per wafer variations), per die (to account for large scale intra-wafer variations) and per device (to fully account for all variations on individual device level). As the tuner efficiencies and FSRs are less sensitive to fabrication variation, in some embodiments these measurements are performed per wafer, but for high-performance devices they can also be performed per device. The choice can also be made on the basis of known process variation statistics and by doing an analysis of achievable precision for the various calibration approaches mentioned above. From the responses of calibration structure(s) and the calibration of the tuning elements, an LUT can be regenerated, using the calibration structure wavelengths as “anchor” points over which tuning map is generated using the (calibrated) powers needed to tune each tuner element. The use of calibration structure wavelengths in this regeneration accounts for aging without requiring external components such as wavemeters, as aging of the calibration structures themselves is minimal as long as temperatures are controlled or measured.

FIG. 12 shows two flow diagrams illustrating some methods to provide calibration of the tunable devices according to embodiments of the present invention, in cases where on-chip elements are used. Such calibrations are typically performed per device, and may be performed before or after devices are singulated from their wafer and/or packaged.

View (1200) shows an illustrative flow of steps for calibrating a tunable laser device using one or more calibration units and on-chip elements, as explained above in relation to FIG. 5. In this illustrative embodiment, the calibration starts by initializing the tunable laser device and initializing the calibration unit(s). Initialization can include operations such as turning on, thermalizing and providing other operations needed for devices to reach an optimal operating state. Once the tunable laser device and calibration unit(s) are properly initialized, we can tune the tunable laser device and determine which tuner controls correspond to precise wavelength responses of the calibration unit(s). In some embodiments, the tuning can flow along the paths described in relation to FIG. 7, but other tuning approaches that similarly cover the full laser tuning range can be utilized. As the laser is tuned across the reference element resonance, we can determine this using on-chip photodetector(s) and record the corresponding tuning signals. They can then be compared to expected tuning signals from earlier calibrations (either similar to this one, or similar to calibrations as described in relation to FIG. 11). Once wavelengths and wavelength responses of the calibration units are determined, they can be suitably recorded and saved in memory. From this data, we can span the full tuning map using calibrations of the individual tuner elements (FSR of each tuner element, power needed to tune each wavelength element by 1 FSR, etc.) and the calibration units as described in relation to FIG. 8, FIG. 9, FIG. 11 and FIG. 12.

View (1250) shows an illustrative flow of steps for calibrating the individual tuning elements of the tunable laser device using on-chip monitor photodetectors, as explained above in relation to FIG. 8. In this illustrative embodiment, the calibration starts by initializing the tunable laser device. In cases where there is an integrated photodetector directly coupled to the laser to monitor laser output, as in FIG. 1 and FIG. 5, the calibration unit need not be initialized. In other cases, where the laser monitoring occurs using one or more photodetectors in the calibration unit, the calibration unit must be initialized. Initialization can include operations such as turning on, thermalizing and providing other operations needed for devices to reach an optimal operating state. Once the tunable laser device is properly initialized, we can tune the individual tuning elements and monitor the on-chip photodetectors' responses to determine the power values needed to tune them by one FSR or span the full tuning range as discussed above in relation to FIG. 8. Once the power values needed to tune by one FSR are determined, they can be suitably recorded and saved in memory. This data can then be used as and when needed, to span the full tuning map using calibrations of the calibration unit and individual heaters.

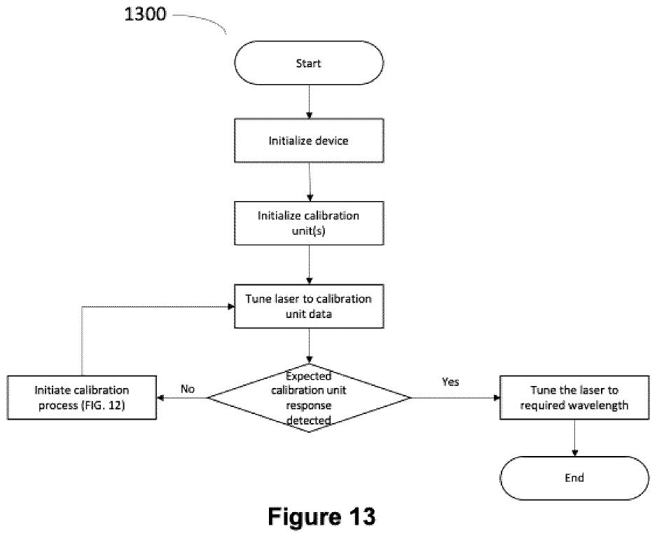

FIG. 13 shows a flow diagram illustrating a method of operating a tunable laser with improved wavelength control, calibrating it as and when necessary, according to one embodiment of the present invention. View (1300) shows an illustrative flow of steps for operating a tunable laser device with calibration units such as those discussed in relation to FIG. 5. In this illustrative embodiment, the operation starts with calibration steps, beginning with initializing the tunable laser device and initializing the calibration unit(s). Initialization can include operations such as turning on, thermalizing and providing other operations needed for devices to reach an optimal operating state. Once the tunable laser device and calibration unit(s) are properly initialized, a calibration check in initiated, in which the tunable laser is tuned to meet expected calibration unit wavelengths using calibration data stored in memory. If the expected calibration unit response is detected, the laser can be operated normally, using LUT(s) that were already stored. If the calibration unit response is different than expected, a new calibration process can be initiated, using algorithms identical or similar to the ones described in relation to FIG. 12 (where only on-chip components are utilized, and no external instruments like wavemeter are needed). Once this new calibration is completed and the LUT is re-generated utilizing calibration data, we can proceed with normal laser operation. Subsequent tuning of the laser can use variations of the tuning procedures outlined in FIGS. 7-9, or may simply mean jumping to a target wavelength using the LUTs that have been regenerated using updated calibration data.

The calibration check can be omitted in some cases (not shown) or can be triggered via various conditions such as e.g. a temperature change that is larger than a predetermined threshold, an acceleration that is larger than a predetermined threshold.

It is clear that various other flow diagrams for calibration and operation can be envisioned, but in all cases calibration, at least in one of the steps, makes use of the calibration unit(s) of the types discussed in this disclosure, with known wavelength response. It is to be understood that these illustrative embodiments teach just some examples of tunable lasers with improved wavelength control. Furthermore, such lasers can be combined with multiple other components to provide additional functionality or better performance such as various filtering elements, amplifiers, monitor photodiodes, modulators and/or other photonic components.

Embodiments of the optical devices described herein may be incorporated into various other devices and systems including, but not limited to, various computing and/or consumer electronic devices/appliances, quantum devices, communication systems, computational systems, medical devices, sensors and sensing systems.

It is to be understood that the disclosure teaches just a few examples of illustrative embodiments and that many variations of the invention can easily be devised by those skilled in the art after reading this disclosure and that the scope of the present invention is to be determined by the following claims.

1. An integrated photonic circuit comprising:
a semiconductor tunable laser comprising:
at least two tuning elements; and
an output port providing a first laser output; and
a calibration structure comprising:
a first reference element having a first reference wavelength response as the semiconductor tunable laser is tuned by adjusting at least one of the tuning elements, the first reference wavelength response comprising a primary peak or valley at a first reference wavelength; and
a first photodetector;
wherein a part of the laser output from the output port is coupled to the calibration structure;
wherein at least part of the first laser output is coupled within the calibration structure to the first reference element; and
wherein at least part of the first laser output leaving the first reference element after being coupled thereto is coupled to the first photodetector.

2. The integrated photonic circuit of claim 1, additionally comprising:
an input port configured to accept a second laser output from a second tunable laser that is external to the integrated photonic circuit;
wherein the input port is coupled to the calibration structure such that a part of the second laser output is coupled to the first photodetector after first being coupled to the first reference element, allowing the first reference wavelength response of the first reference element to be determined.

3. The integrated photonic circuit of claim 1,
wherein the calibration structure comprises a second photodetector; and
wherein the second photodetector is coupled to a second part of the first laser output coupled to the calibration structure, the second part of the first laser output not having first been coupled to the first reference element.

4. The integrated photonic circuit of claim 1,
wherein the first reference element comprises a grating.

5. The integrated photonic circuit of claim 1,
wherein the first reference element comprises a contra-directional coupler.

6. The integrated photonic circuit of claim 1,
wherein the calibration structure additionally comprises:
a second reference element having a second reference wavelength response, different from the first reference wavelength response, as the semiconductor tunable laser is tuned by adjusting at least one of the tuning elements, the second reference wavelength response comprising a second primary peak or valley at a second reference wavelength different from the first reference wavelength; and
a third photodetector;
wherein a third part of the first laser output is coupled within the calibration structure to the second reference element; and
wherein at least part of the first laser output leaving the second reference element after being coupled thereto is coupled to the third photodetector.

7. The integrated photonic circuit of claim 6,
wherein the calibration structure additionally comprises a fourth photodetector; and
wherein the fourth photodetector is coupled to a fourth part of the first laser output coupled to the calibration structure, the fourth part of the first laser output not having first been coupled to the second reference element.

8. The integrated photonic circuit of claim 6,
wherein the calibration structure additionally comprises a third reference element and a fifth photodetector; and
wherein at least part of the first laser output that is coupled to the calibration structure is coupled to the third reference element; and
wherein at least part of the laser output that is coupled to the third reference element is coupled to the fifth photodetector, and
wherein the third reference element has unique wavelength response, that is different from the wavelength responses of both first and second reference elements, that can be detected by the response of the fifth photodetector as laser is tuned by at least one of the tuning elements.

9. The device of claim 8,
wherein the calibration structure additionally comprises a sixth photodetector; and
wherein the sixth photodetector is coupled to the laser output not having first been being coupled to the third reference element.

10. The integrated photonic circuit of claim 1,
wherein the calibration structure additionally comprises a first calibration tuning element configured to tune the first reference wavelength response.

11. The integrated photonic circuit of claim 1,
wherein the calibration structure additionally comprises a thermistor element configured to measure a temperature characterizing at least a part of the calibration structure.

12. The integrated photonic circuit of claim 1,
wherein the semiconductor tunable laser additionally comprises a seventh photodetector;
wherein at least a part of the semiconductor tunable laser output is coupled to the seventh photodetector; and
wherein the seventh photodetector is configured to monitor the output power as at least one of the tuning elements is tuned.

13. The integrated photonic circuit of claim 1,
wherein the semiconductor tunable laser additionally comprises a semiconductor optical amplifier (SOA) with an SOA input port and an SOA output port; and
wherein at least a part of the first laser output is coupled to the SOA input port as an SOA input; and
wherein the SOA is configured such that an amplified version of the SOA input is provided at the SOA output port.

14. The integrated photonic circuit of claim 13,
wherein the semiconductor tunable laser additionally comprises an SOA monitor photodetector; and
wherein at least a part of the amplified version of the SOA input is coupled to the SOA monitor photodetector, such that the SOA monitor photodetector provides an indication of the first laser output.

15. The integrated photonic circuit of claim 1,
wherein the reference element is a grating.

16. The integrated photonic circuit of claim 15,
wherein the grating includes a phase shift defect.

17. The integrated photonic circuit of claim 1,
wherein the reference element is a contra-directional coupler.
